(19) United States
(12) Patent Application Publication
(10) Pub. No.: US 2003/0068892 A1
(43) Pub. Date: Apr. 10, 2003

(54) Metal shadow-mask in IC process flow

(76) Inventor: Chief Lin, Kaohsiung City (TW)

Correspondence Address: RABIN & BERDO, P.C., Suite 500, 1101 14th Street, N.W., Washington, DC, 20005, US

(21) Appl. No.: 09/971,601

(22) Filed: Oct. 9, 2001

(51) Int. Cl. H01L 21/302; H01L 21/461

(52) U.S. Cl. 438/692

(57) ABSTRACT

The present invention provides a method of metal shadow-mask in process flow, which replaces the conventional photomask(s) and applies to the procedures of IC manufacturing to achieve the same efficiency as photomask(s). Additionally, the present invention can combine with photosensitive resist defined pattern to lessen a number of photomask(s) and complex procedures in IC manufacturing, especial in SOC, as well as decrease the cost of mask(s).

### TECHNICAL FIELD

The present invention relates to a method of metal shadow-mask in process flow. Namely, by defined a metal material for using in the surface of shadow-mask, after exposing the photosensitive resist to form a pattern, then by dry-/wet-etching the pattern onto. Since the shadow-mask is been completed, by laying said mask upon a raw wafer to process the etching, film growth and implantation onto said wafer.

Different divisions, e.g. logic and memory divisions, in same chip will need different process requirements on each division. To reach the requirement, the device performance sacrifice or increase mask or apply defined the same metal material as aforesaid companying with photosensitive resist defined pattern for partial shadowing and following the aforesaid procedures to process onto said wafer. Stepping by stepping the one shadow mask or more to achieve the one partial shield pattern or more partial shield patterns which is/are according the needs of said wafer. Then said wafer will be taken away when the aforementioned processes and procedure are been completed, thus said pattern or patterns has/have different process requirement, is/are defined onto said wafer and a perfect wafer is born.

### BACKGROUND OF THE PRESENT INVENTION

Photomask is an essential and an initiate procedure for completion of a wafer designing and processing. The photomask is to transfer the program designed document of been completed in the interior electronic circuits or pattern of IC into MEBS language document for the photomask equipment to read. The other photomask manufacturing equipment use the laser beam or E-beam to expose the interior electronic circuits or pattern of IC onto the chrome film of crystal glass of photomask. Thus, an entire image of interior electronic circuits or pattern will present onto said photomask, then by means of etching to etch the chrome film on the electronic circuits. So repeating and repeating those procedures of exposure, development and etching in the photomask that is to be conferred the needs of IC. Then taking this a completed photomask to process of wafer manufacture. Since the interior electronic circuits or pattern of IC on the photomask will transfer and print onto the wafer and generate every of new ICs. Aforementioned procedures in making a photomask are very complex and overlap and too expensive.

The present invention of metal shadow-mask is to make the pattern as preferable required onto the metal shadow-mask, then putting it above the wafer. So, the times and cost of photomask usage will be decreased, furthermore, as well as the related accordant procedures, such as photosensitive resist, will be reduced.

Otherwise, a wafer has various divisions and layers, most of them need different levels of complicate or precise or simple manufacturing procedures and photomasks. For example a design of system on chip, SOC, of its interlock-in memory units and logic memory units shall be implanted different junction depth into different divisions or different thickness of gate oxide layer. It is obviously that those different device requirements will increase photomasks in standard IC flow, for example, capacitors been designed at the deeper trench of DRAM. Under this result that it is necessary to define the deep trench capacitor by another mask. Additionally, the different demands of manufacturing procedures in every division and layer level can be utilized the metal shadow-mask, which also accompanies with the photosensitive resist to define a certain pattern to proceed shadowing procedure in every partial code of said division. Thus, an essential role of the present invention is to integrate those complicate and precise procedures into easier and simpler, which will lessen the numbers of photomasks and manufacturing expense, so this tendency will become a mainstream to dominate the photomask-industry in the future.

According to aforementioned demands, the inventor devotes himself to the photomask industrial manufacturing and designing and its peripherals. Hence, the accordant efficiency to lessen the numbers of photomasks and decrease manufacturing expensive in the present invention is developed.

### SUMMARY OF THE PRESENT INVENTION

It is an object of the present invention to lessen the numbers of photomask and to decrease the complicate and inextricable procedures during the ICs' processing.

The other object of the present invention is to provide the reduction of photomask manufacturing procedures, and to simplify the partial procedures of photomask manufacturing.

Another object of the present invention is that every metal shadow-mask only proceed etching, or film growth, or implantation onto every division or code or layer onto the wafer, otherwise said mask has no effect onto the other divisions, or codes or layers which are not ongoing processing.

The other object of the present invention is to provide an, or more differently functional metal shadow-mask(s) to proceed partial-etching, or partial-film growth, or partial implantation onto assigned division or assigned code or assigned layer onto the wafer.

In order for the Committees to more understand the efficiencies, objects and features of the present invention, following with drawings and a practical example as reference.

### BRIEF DESCRIPTION OF DRAWINGS

FIG. 1, shown as a metal shadow-mask is going through the procedures of photosensitive resist, exposure and etching.

FIG. 2, a diagram shown as a wafer had been placed beneath the metal shadow-mask.

FIG. 3, a diagram shown as ongoing manufacturing processes, including etching, film growth and implantation, between the metal shadow-mask and wafer.

FIG. 4, a post state of wafer had passed through the manufacturing procedures.

FIG. 5, shown as the first or more metal shadows-mask is going through the procedures of photosensitive resist, exposure and etching.

FIG. 6, shown as a wafer had been placed beneath the first metal shadow-mask.

FIG. 7, a diagram shown as ongoing manufacturing processes between the wafer and partial image of the first, or metal shadow-mask, to get partial process on the open area by partial shielding shadow mask.

FIG. 8, a diagram shown as a wafer had been completed the manufacturing processes by the first or more metal shadow-masks.

### DESCRIPTION OF TERMS

(10) metal shadow-mask

(11) pattern

(20) wafer

(30) the secondary, or more metal shadow-mask

(31) pattern

### DETAILED DESCRIPTION OF THE PRESENT INVENTION

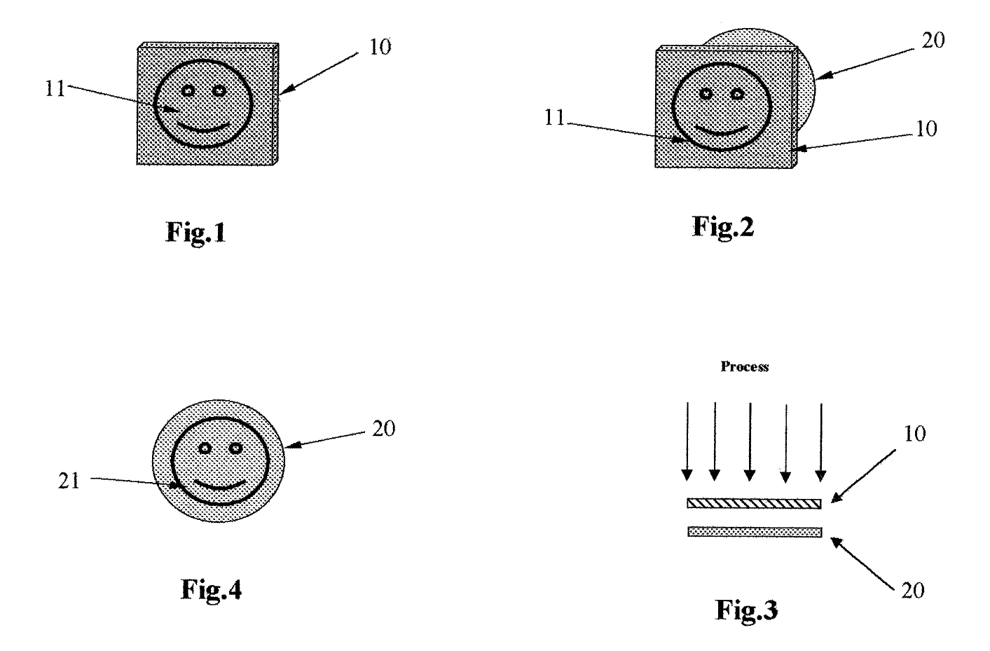

As defined a metal shadow-mask (10) to posses the procedures of photosensitive resist and exposure to form a pattern (11), then by using of wet/dry etching to etch said pattern (11) shown as FIG. 1. Then placed the wafer (20) beneath the etched mask (10) (shown as FIG. 2) and to direct process the procedures of etching, or film growth, or implantation onto both of said mask and wafer (shown as FIG. 3). Since said procedures have been completed, a manufactured wafer (20) is able to take away and the pattern of said mask (11) had been transferred into and printed on the wafer (20) (shown as FIG. 4).

The metal shadow-mask (20) is also capable of processing a partial shadowing, by means of shadowing the division (21) of a partial code which on the upper section of the wafer (20).

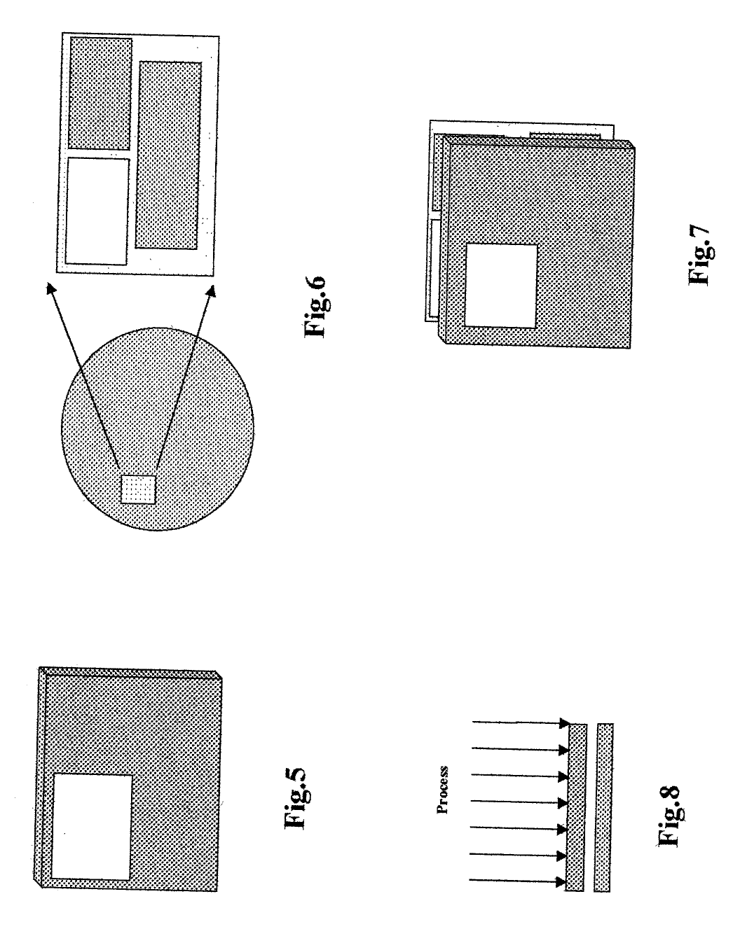

Please refer to FIGS. 5 from 8, by putting the wafer (20) beneath the metal shadow-mask (30) which had been finished the procedures of photosensitive resist, exposure and etching. So the cover of the mask (30) will present the other pattern (31). The wafer is defined by Photosensitive resist. Then, proceeding the partial shielding process onto both of the wafer (20) and the mask, hence those procedures of etching, or film growth, or ion implantation will via the mask (30) to function onto a certain division of chip of the wafer (20) until said procedures are completed. Then removing said mask away and placing a new mask to process for other division of chip as said procedures accordingly. If it is necessary to process another or more process conditions to another division or more divisions onto chip of said wafer (20), following aforementioned said step and step to place and move the third, fourth . . . , and as aforementioned every procedure of etching, or film growth, or implantation as routine which will print said pattern and pattern onto individual code or codes by combining photosensitive resist and partial shadow mask to reach the different process requirement on relative divisions. Since all codes are completed that shows a perfect wafer is born. Finally, the perfect wafer can be shifted out. Accordingly, by means of redoing said process one time, as it is a requirement that the other metal shadow-mask must be partial shielded onto a certain code of the wafer (20). Obviously, every metal shadow-mask can apply to the various division or code of said wafer to complete the various demand of shadowing procedure by this matter.

According to aforementioned, the present invention is practical, utility and patentable that confers the regulations of Patent Laws.

What is claimed is:

1. A method of metal shadow-mask in process flow, herein defined a shadow-mask thought the prior processing in photosensitive resist, exposure and the like to form a pattern and to etch said pattern; then placing a wafer beneath said mask for etching, film growth or implantation and allowing to take said wafer away since completed the above processes.

2. According to claim 1, the substrate of metal shadow-mask is made of metal material.

3. According to claim 1, by means of dry etching to etch said pattern of wafer.

4. According to claim 1, entire manufacturing process of ICs by means of this shadow-mask herein no more photomask is required.

5. A method of metal shadow-mask in process flow, herein defined a shadow-mask thought the prior processing in photosensitive resist, exposure and the like to form a pattern and to etch said pattern; then placing a photosensitive resist pattern defined wafer beneath said mask for etching, film growth or implantation on the assigned division of wafer (chip), hereafter repeating above procedures by another or more shadow masks to do another or more process conditions, wherewith a whole schedule of different processes in every of divisions of entire wafer (chip) is completed.

6. According to claim 5, said method is capable of manufacturing procedures by partial shadow with photosensitive resist pattern to complete different process and procedure onto the same wafer without increasing more photomasks.

7. According to claim 5, said mask can be made in various feature or mode to fit in different mode demand of wafer to be processed.

8. According to claim 5, the various feature or mode of said mask only can process the procedures of etching, film growth and implantation onto the wafer and having no effect to the other portion of division(s), code(s), layer(s) of said wafer while said procedures are ongoing onto defined portion of said wafer.

9. According to claim 8, every various feature or mode of said mask can respectively in turn process onto said wafer.
